(19) United States
(12) Patent Application Publication
(10) Pub. No.: US 2015/0270150 A1
(43) Pub. Date: Sep. 24, 2015

(54) BOAT

(71) Applicant: TERASEMICON CORPORATION, Hwaseong-si (KR)

(72) Inventors: Han Kil YOO, Osan-si (KR); Woo Yong CHOI, Osan-si (KR)

(21) Appl. No.: 14/665,136

(22) Filed: Mar. 23, 2015

(30) Foreign Application Priority Data
Mar. 24, 2014 (KR) 10-2014-0034304

(51) Int. Cl. H01L 21/673

(52) U.S. Cl. CPC H01L 21/67309

(57) ABSTRACT

A boat for loading a plurality of substrates to be vertically stacked includes a ring holder for supporting a bottom part of each substrate and mounting the substrate, and a plurality of support rods for supporting a bottom part of the ring holder and having first ends to mount the ring holder, wherein the ring holder and the support rods are integrally connected to each other within a projected area of the substrates.

### CROSS REFERENCE TO RELATED PATENT APPLICATION

This application claims priority to and the benefit of Korean Patent Application No. 10-2014-0034304 filed in the Korean Intellectual Property Office on Mar. 24, 2014, the entire contents of which are incorporated herein by reference.

### BACKGROUND

1. Field

The present invention relates to a boat and, more particularly, to a boat in which a ring holder and support rods are integrally connected to each other within a projected area of substrates.

2. Description of Related Technology

A substrate treating apparatus includes a vapor deposition apparatus and an annealing apparatus.

The vapor deposition apparatus is an apparatus for forming a transparent conductive layer, an insulating layer, a metal layer or a silicon layer as a core element of a semiconductor, and includes a chemical vapor deposition (CVD) apparatus such as a low pressure chemical vapor deposition (LPCVD) apparatus or a plasma-enhanced chemical vapor deposition (PECVD) apparatus, and a physical vapor deposition (PVD) apparatus such as a sputtering apparatus.

The annealing apparatus is an apparatus for performing a heat-treatment process which is essential for crystallization, phase transformation, etc. of a thin film deposited on a substrate such as a silicon wafer used to manufacture a semiconductor.

FIG. 1 is a perspective view of a conventional batch-type substrate treating apparatus. This conventional batch-type substrate treating apparatus is disclosed in Korean patent application No. 2012-0125073.

Referring to FIG. 1, in the conventional batch-type substrate treating apparatus, a boat 100 in which a plurality of substrates 10 are vertically stacked and loaded is disposed in a reaction chamber (not shown) having an opening at the bottom to define an accommodation space therein and to perform a semiconductor manufacturing process.

The loading/unloading of the substrates 10 onto/from the boat 100 is transferred from a cassette (not shown) mounted on a stage (not shown) by an end effector 200 of a robotic arm.

The boat 100 includes three vertical frames 120: 121 and 125 in a pole shape, and support rods 110: 111 and 115, the number of which is the same as the substrates 10, protrude from each of the vertical frames 120.

The three support rods 110 protruding respectively from the three vertical frames 120 are on the same plane and support a bottom part of a ring holder 130. Here, the support rods 110 support the bottom part of the ring holder 130 at three points equally spaced by 120° on the circumference.

The substrate 10 may be mounted on the ring holder 130. The ring holder 130 in a ring shape may support a bottom part of the substrate 10 on a circular area.

The end effector 200 of a bottom-lift type may enter the boat 100 above the support rods 110 to support the bottom part of the substrate 10 while occupying a space on the same plane as the ring holder 130 and may load or unload the substrate 10 through a front opening 5.

In this conventional batch-type substrate treating apparatus, since the ring holder 130 should be mounted on the support rods 110, a transfer robot (not shown) is needed for mounting the ring holder 130 from the outside onto the support rods 110, and a cassette (not shown) exclusive to the ring holder or a FOUP (not shown) exclusive to the ring holder for accommodating the ring holder 130 is also necessary. Furthermore, control software related thereto needs to be developed. As such, costs increase and the apparatus becomes complicated.

In addition, it is problematic that fine particles generated due to fraction while the ring holder 130 is mounted on the support rods 110 contaminate the substrate 10.

Besides, misalignment of 3 mm or less that is caused when the ring holder 130 is mounted on the support rods 110 cause the substrate 10 loaded onto the ring holder 130 to be equally misaligned.

### SUMMARY

The present invention provides a boat having a simple structure and being capable of reducing manufacturing costs thereof by having a ring holder and support rods integrally connected to each other.

The present invention also provides a boat capable of improving alignment of substrates and preventing contamination of the substrates.

According to an aspect of the present invention, there is provided a boat for loading a plurality of substrates to be vertically stacked, the boat including a ring holder for supporting a bottom part of each substrate and mounting the substrate, and a plurality of support rods for supporting a bottom part of the ring holder and having first ends to mount the ring holder, wherein the ring holder and the support rods are integrally connected to each other within a projected area of the substrates.

According to the present invention, since a ring holder and support rods are integrally connected to each other, a boat may have a simple structure and a manufacturing cost thereof is reduced.

Furthermore, alignment of substrates may be improved and contamination of the substrates may be prevented.

### BRIEF DESCRIPTION OF THE DRAWINGS

FIG. 1 is a perspective view of a conventional batch-type substrate treating apparatus.

FIG. 2 is a perspective view of a batch-type substrate treating apparatus according to a first embodiment of the present invention.

FIG. 3 is a plan view of a structure wherein support rods and a ring holder are connected to each other according to the first embodiment of the present invention.

FIGS. 4A to 4C are plan views and cross-sectional views of the batch-type substrate treating apparatus according to the first embodiment of the present invention.

FIG. 5 is a perspective view of a batch-type substrate treating apparatus according to a second embodiment of the present invention.

FIG. 6 is a plan view of a structure wherein support rods and a ring holder are connected to each other according to the second embodiment of the present invention.

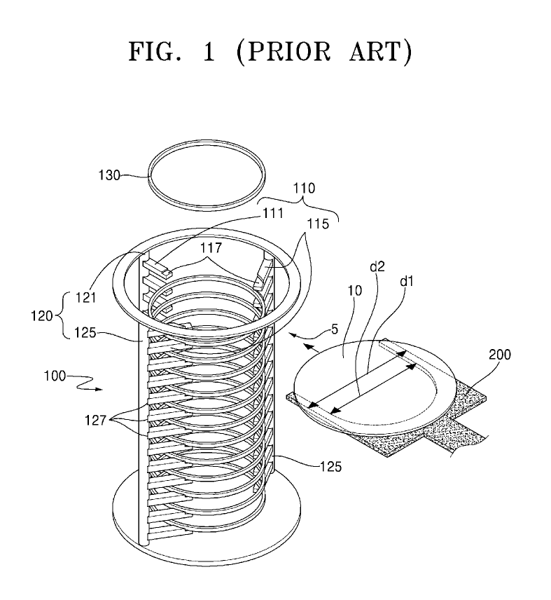

### DETAILED DESCRIPTION

The present invention will now be described more fully hereinafter with reference to the accompanying figures, in which embodiments of the invention are shown. The present invention may, however, be embodied in many alternate forms and should not be construed as limited to the embodiments set forth herein. Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the drawings, the thickness of layers and regions are exaggerated for clarity.

In this specification, a batch-type substrate treating apparatus may be understood to include a series of devices for treating substrates, e.g., a reaction chamber, a boat, an end effector of an robotic arm, a stage and a cassette. For convenience of explanation, however, a boat and an end effector will be described below as the elements of a batch-type substrate treating apparatus.

Furthermore, in this specification, substrates may be understood to include semiconductor substrates, substrates for display devices such as light emitting diode (LED) and liquid crystal display (LCD) devices, solar cell substrates, etc.

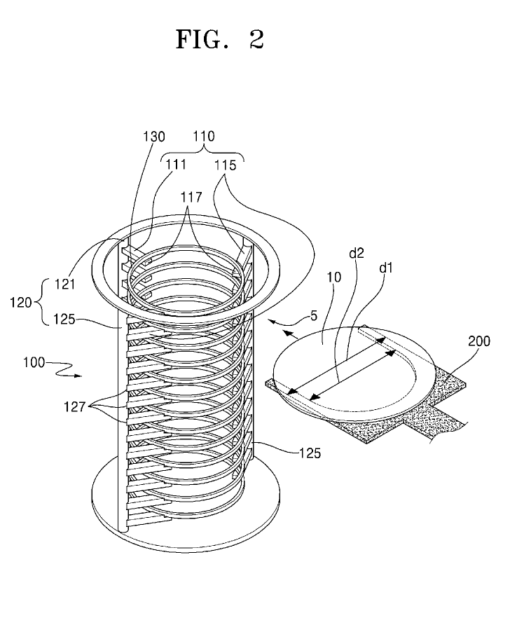

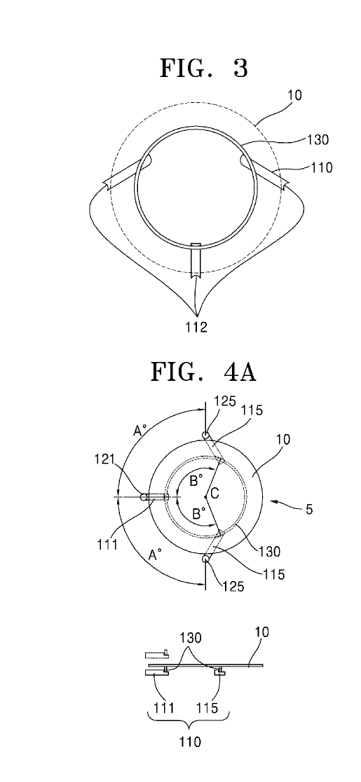

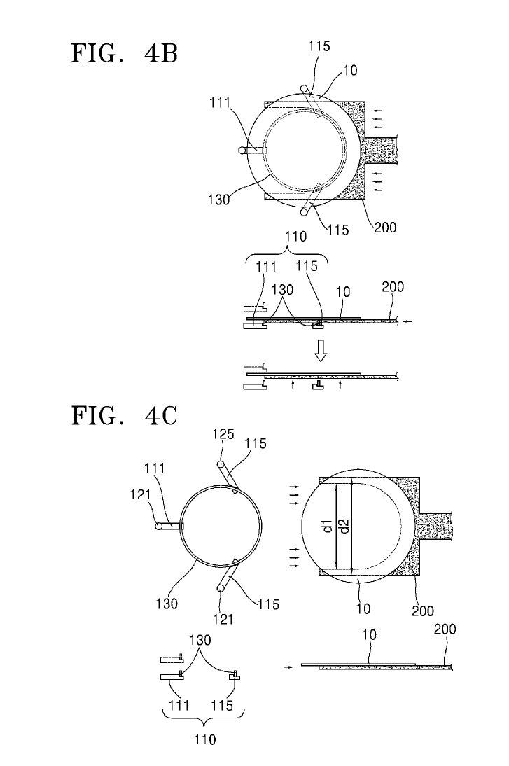

FIG. 2 is a perspective view of a batch-type substrate treating apparatus according to the first embodiment of the present invention, FIG. 3 is a plan view of a structure in which support rods 110 and a ring holder 130 are connected to each other according to the first embodiment of the present invention, and FIGS. 4A to 4C are plan views and cross-sectional views of the batch-type substrate treating apparatus according to the first embodiment of the present invention.

Referring to FIGS. 2 to 4, the batch-type substrate treating apparatus according to the first embodiment of the present invention includes a boat 100 and a bottom-lift type end effector 200.

The boat 100 is a boat for a batch-type substrate treating apparatus in which a plurality of substrates 10 can be loaded to be vertically stacked. The boat 100 may be made of at least one material selected from quartz, silicon carbide (SiC), graphite, carbon composite and silicon (Si).

The boat 100 may include a plurality of vertical frames 120: 121 and 125 formed in a pole shape, and preferably three vertical frames 121 and 125. The following description assumes that the number of vertical frames 120 of the boat 100 is three.

When an imaginary circle is given to correspond to a horizontal cross-section of the boat 100 having a substantially cylindrical shape, the three vertical frames 120 may be formed to occupy a space that corresponds to about half (½) of the circumference of the imaginary circle. A space that corresponds to the other half (½) of the circumference of the circle, which is not occupied by the three vertical frames 120, defines a front opening 5 for allowing insertion of the end effector 200 to allow loading/unloading of the substrates 10.

Although the angle A between the vertical frame 121 located in a direction parallel to the work path of the end effector 200, and the other two vertical frames 125 is depicted to be 91° in FIGS. 2 to 4, the angle A between the vertical frame 121 and the vertical frames 125 is not limited thereto and may be from 91° to 120° as long as the insertion of the end effector 200 into the boat 100 is allowed. A detailed description thereof will be given below.

Support rods 110: 111 and 115 may protrude from the vertical frames 120 to the inside of the boat 100 on the same plane, the ring holder 130 may be integrally connected to the support rods 110, and the support rods 110 and the ring holders 130 may be disposed at regular intervals along the height direction thereof.

The present invention is characterized in that the ring holder 130 and the support rods 110 are integrally connected to each other within a projected area of the substrates 10. Here, the projected area of the substrates 10 may refer to a virtual cylindrical space defined by connecting all the spaces occupied by the substrates 10 that are stacked in the boat 100.

The support rods 110 may support the bottom part of the ring holder 130 in such a manner that the ring holder 130 is disposed on first ends of the support rods 110. The support rods 110 and the ring holder 130 may be made of the same material as the boat 100 to be resistant to a high-temperature environment and a chemical environment of a reaction process. The support rods 110 and the ring holder 130 may be prepared separately and then integrally connected to each other by, for example, welding, or may be integrally formed from the beginning.

Steps 117 may be provided on the first ends of the support rods 110 such that the ring holder 130 is more stably mounted.

After the support rods 110 and the ring holder 130 are integrally formed, second ends 112 of the support rods 110 and the vertical frames 120 of the boat 100 may be connected to each other to complete the boat 100. Here, the second ends 112 of the support rods 110 and the vertical frames 120 may be connected to each other by, for example, welding, or by inserting the second ends 112 of the support rods 110 into recesses 127 in the vertical frames 120.

As described above, according to the present embodiment, since the support rods 110 and the ring holder 130 are integrally formed and then are connected to the vertical frames 120 to complete the boat 100, a manufacturing process of the boat 100 may become simpler. Furthermore, since devices such as a ring holder transfer robot (not shown) for transferring the ring holder 130, a cassette (not shown) exclusive to the ring holder, and a FOUP (not shown) exclusive to the ring holder are not needed and software related to transfer and control of the ring holder 130 may not need be developed, thereby drastically reducing development and production costs of products. In addition, contamination of the substrate 10 caused by fine particles generated due to fraction while the ring holder 130 is mounted on the support rods 110 may be prevented, and the problem of misalignment caused when the ring holder 130 is mounted on the support rods 110 may also be solved.

When the substrate 10 is heat-treated at ultrahigh temperatures (from about 1,200 to about 1,350° C.), the substrate 10 and the ring holder 130 may be sagged. Thus, the ring holder 130 should be supported at three points equally spaced apart from each other by 120° in such a manner that the support rods 110 can uniformly support the weights of the ring holder 130 and the substrate 10 on the ring holder 130.

However, when the substrate 10 is heat-treated at medium to high temperatures (from about 500 to about 800° C.), sagging of the substrate 10 and the ring holder 130 may be reduced and therefore the need for supporting the ring holder 130 at three points equally spaced apart from each other by 120° may be reduced. Accordingly, when heat-treatment is performed at medium to high temperatures, the three points at which the support rods 110 contact the ring holder 130 may be spaced from each other by 91° to 150°. Particularly, referring to FIGS. 4A to 4C, the angle B between a point at which the support rod 111 that protrudes toward the center point C from the vertical frame 121 located in a direction parallel to the work path of the end effector 200 contacts the ring holder 130, and points at which the support rods 115 that protrude from the neighboring two vertical frames 125 contact the ring holder 130 may be from 91° to 150°.

The ring holder 130 is utilized to prevent slip, which is a crystal defect in a silicon lattice of the substrate in a high temperature heat treatment process, and may be used to support the bottom part of the substrate 10 having a large diameter (300 mm or 450 mm) and to structurally prevent sagging of the substrate 10.

To stably support the substrate 10, the ring holder 130 may be disposed in such a manner that the central axis (or center point C) of the ring holder 130 coincides with the central axis (or center point C) of the substrate 10. Here, the central axis (or center point C) may refer to a normal line of the center of mass (or the point of the center of mass (the origin)) of the ring holder 130 or a normal line of the center of mass (or the point of the center of mass (the origin)) of the substrate 10. In order for the ring holder 130 to effectively and uniformly support the substrate 10, the diameter of the ring holder 130 may be 0.6 to 0.8 times the diameter of the substrate 10. In particular, the diameter of the ring holder 130 may be 0.7 times the diameter of the substrate 10 such that half of the area of the substrate 10 is supported inside of the ring holder 10 while the other half is supported outside of the ring holder 10. However, the diameter of the ring holder 130 is not limited thereto, and may vary depending on the processing temperature, the size and strength of the substrate, etc.

Furthermore, when the diameter of the substrate 10 is 300 mm, a ring width of the ring holder 130 may be 2 mm to 25 mm and, more preferably, 2 mm to 5 mm. When the diameter (external diameter) of the ring holder 130 is 210 mm, which is 0.7 times the diameter of the substrate 10, if the ring width of the ring holder 130 is set to 2 mm to 25 mm, the area of the substrate 10 that contacts the ring holder 130 may account for about 1.85% to about 20.56%. If the ring width of the ring holder 130 is set to 2 mm to 5 mm, the area of the substrate 10 that contacts the ring holder 130 may account for about 1.85% to about 4.56%. In other embodiment, when the diameter (external diameter) of the ring holder 130 is set to 199 mm, if the ring width of the ring holder 130 is set to 2 mm to 25 mm, the area of the substrate 10 that contacts the ring holder 130 may account for about 1.85% to about 15.56%. If the ring width of the ring holder 130 is set to 2 mm to 5 mm, the area of the substrate 10 that contacts the ring holder 130 may account for about 1.75% to about 4.31%. Accordingly, if the ring width of the ring holder 130 is set to 2 mm to 5 mm, only an area smaller than about 5% of the area of the substrate 10 contacts the ring holder 130, thereby reducing scratches on the bottom part of the substrate 10 and preventing sagging of the substrate 10.

Even when the diameter of the substrate 10 is 450 mm, the size of area of the substrate 10 that contacts the ring holder 130 may be controlled by adjusting the ring width of the ring holder 130 as long as scratches on the bottom part of the substrate 10 are reduced and sagging of the substrate 10 is prevented.

The end effector 200 of a bottom-lift type may load the substrate 10 into or unload the substrate from the boat 100.

Referring back to FIGS. 4A to 4C, the bottom-lift type end effector 200 according to an embodiment of the present invention enters the boat 100 while occupying a space on the same plane as the ring holder 130 from the outside of an outer circumferential surface of the ring holder 130, and may load or unload the substrate 10 by supporting the bottom part of the substrate 10. To avoid interference with the ring holder 130 when the bottom-lift type end effector 200 enters the boat 100, the end effector 200 may have a U-shape. Furthermore, as illustrated in the plan view of FIG. 4B, since the end effector 200 has a U-shape, interference with the support rod 111 that protrudes from the vertical frame 121 may also be avoided. Besides, as illustrated in the cross-sectional view of FIG. 4B, the end effector 200 is located higher than the support rods 115 such that the end effector 200 does not contact the support rods 115 but contacts the ring holder 130 as the end effector 200 moves into the boat 100, thereby solving the problem of interfering with the support rods 115 that protrude from the two vertical frames 125. In other words, since the end effector 200 is located higher than the support rods 115 that protrude from the two vertical frames 125, interference therebetween may be avoided.

In addition, to stably and effectively support the substrate 10 while avoiding interference with the ring holder 130, a distance d1 between two inner side surfaces of the end effector 200 may be greater than the diameter of the ring holder 130, and a distance d2 between two outer side surfaces of the end effector 200 may be smaller than the diameter of the substrate 10.

In an embodiment, when the diameter of the substrate 10 is 300 mm, the distance d1 between the two inner side surfaces of the end effector 200 is set to 200 mm to 220 mm and the distance d2 between the two outer side surfaces of the end effector 200 is set to 244 mm to 260 mm, thereby avoiding interference between the ring holder 130 and the two vertical frames 125 and easily loading/unloading the substrate 10.

In other embodiments, when the diameter of the substrate 10 is 450 mm, the distance d1 between the two inner side surfaces of the end effector 200 is set to 300 mm to 330 mm and the distance d2 between the two outer side surfaces of the end effector 200 is set to 366 mm to 390 mm, thereby avoiding interference between the ring holder 130 and the two vertical frames 125 and easily loading/unloading the substrate 10.

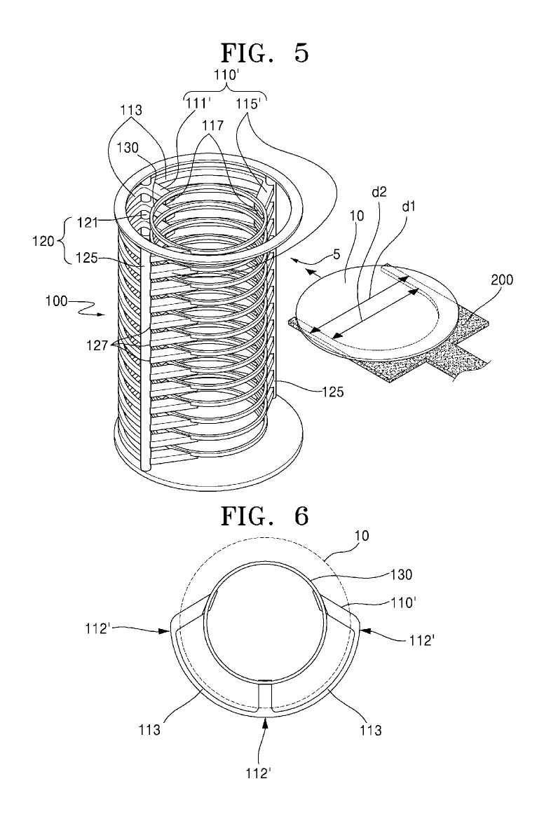

FIG. 5 is a perspective view of a batch-type substrate treating apparatus according to the second embodiment of the present invention, and FIG. 6 is a plan view of a structure in which support rods 110′ and a ring holder 130 are connected to each other according to the second embodiment of the present invention.

The following description with reference to FIGS. 5 and 6 will be about the differences from the description with reference to FIGS. 2 to 4 and repeated descriptions will be omitted.

Referring to FIGS. 5 and 6, the second embodiment of the present invention is characterized in that the ring holder 130, the support rods 110′ and a connector 113 are integrally connected to each other.

The connector 113 may connect second ends 112′ of the support rods 110′ to each other. The connector 113 may have a substantially semicircular arc shape. As such, the connector 113 may connect the second ends 112′ of the support rods 110′ to each other while occupying a space that accounts for about half (½) the circumference of an imaginary circle that corresponds to a horizontal cross section of the boat 100.

The support rods 110′ and the connector 113 may be integrally formed from the beginning or may be prepared separately and then integrally connected to each other by, for example, welding. In addition, the integrally formed support rods 110′ and the connector 113 may be integrally connected to the ring holder 130 by, for example, welding. Alternatively, the support rods 110′, the connector 113 and the ring holder 130 may be integrally formed from the beginning.

After the support rods 110′, the connector 113 and the ring holder 130 are integrally formed, the second ends 112′ of the support rods 110′ and the vertical frames 120 of the boat 100 may be connected to each other to complete the boat 100 according to the embodiment. Here, the second ends 112′ of the support rods 110′ and the vertical frames 120 may be connected to each other by, for example, welding, or by inserting the second ends 112′ of the support rods 110′ into the recesses 127 in the vertical frames 120.

Hereinafter, loading/unloading of the substrate 10 into or from the boat 100 using the bottom-lift type end effector 200 will be described with reference to FIGS. 2 and 4. While FIGS. 4A to 4C illustrate unloading of the substrate 10, loading of the substrate 10 may be understood as the reverse of the unloading.

Referring to FIG. 4A, the ring holder 130 is integrally connected to the first ends of the three support rods 110 that protrude from the vertical frames 121 and 125, and the substrate 10 is mounted on the ring holder 130 in such a manner that the central axis (or center point C) of the substrate 10 coincides with the central axis (or center point C) of the ring holder 130.

Then, referring to FIG. 4B, the bottom-lift type end effector 200 enters the boat 100 through the front opening 5. Here, since the end effector 200 has a U-shape to surround the outer circumferential surface of the ring holder 130, the distance d1 between the two inner side surfaces of the end effector 200 is greater than the diameter of the ring holder 130, the distance d2 between the two outer side surfaces of the end effector 200 is smaller than the diameter of the substrate 10, and the end effector 200 occupies a space on the same plane as the ring holder 130 outside the outer circumferential surface of the ring holder 130 and is located higher than the support rods 115 that protrude from the two vertical frames 120, the end effector 200 may enter and be located under the substrate 10 while avoiding interference with the ring holder 130 or the support rods 110. The end effector 200 lifts the substrate 10 such that the substrate 10 is spaced apart from the ring holder 130 by a certain height.

Then, referring to FIG. 4C, the end effector 200 may support only the substrate 10 and unload the substrate 10 from the boat 100.

As described above, by using the bottom-lift type end effector 200 according to the embodiment, it is advantageous that the substrate 10 may be loaded or unloaded by a height by which the substrate 10 and the ring holder 130 is spaced apart from each other. Accordingly, the number of substrates 10 loaded into the boat 100 may be increased and thus a larger number of substrates 10 may be treated per unit process.

While the present invention has been particularly shown and described with reference to embodiments thereof, it will be understood by a person having ordinary skill in the art that various changes in form and details may be made therein without departing from the spirit and scope of the present invention as defined by the following claims.

What is claimed is:

1. A boat for loading a plurality of substrates to be vertically stacked, the boat comprising:
a ring holder that supports a bottom part of the substrate and on which the substrate is mounted; and
a plurality of support rods that supports a bottom part of the ring holder and that includes first ends on which the ring holder is mounted,
wherein the ring holder and the support rods are integrally connected to each other within a projected area of the substrate.

2. The boat of claim 1,
further comprising a connector that connects second ends of the support rods to each other,
wherein the ring holder, the support rods and the connector are integrally connected to each other.

3. The boat of claim 2,
wherein the connector has a semicircular arc shape.

4. The boat of claim 1,
wherein the number of support rods is three, and
wherein the three support rods support the ring holder at three supporting points.

5. The boat of claim 4,
further comprising a plurality of vertical frames,
wherein second ends of the support rods are integrally connected to the vertical frames.

6. The boat of claim 1,
wherein steps are formed on the first ends of the support rods.

7. The boat of claim 1,
wherein a diameter of the ring holder is 0.6 times to 0.8 times a diameter of the substrate.

8. The boat of claim 1,
wherein a diameter of the substrate is 300 mm, and
wherein a ring width of the ring holder is 2 mm to 25 mm.

9. The boat of claim 8,
wherein the ring width of the ring holder is 2 mm to 5 mm.

10. The boat of claim 5,
wherein three-point supporting angles of the ring holder are divided by an angle of 91° to 150° by adjusting a protruding angle of the support rods that protrude from the vertical frames.

11. The boat of claim 1,
wherein the boat comprises at least one material selected from quartz, silicon carbide (SiC), graphite, carbon composite and silicon (Si).

12. The boat of claim 2,
wherein the number of support rods is three, and
wherein the three support rods support the ring holder at three supporting points.

13. The boat of claim 12,
further comprising a plurality of vertical frames,
wherein second ends of the support rods are integrally connected to the vertical frames.

14. The boat of claim 13,
wherein three-point supporting angles of the ring holder are divided by an angle of 91° to 150° by adjusting a protruding angle of the support rods that protrude from the vertical frames.
